(19) United States
(12) Patent Application Publication
(10) Pub. No.: US 2008/0266012 A1
(43) Pub. Date: Oct. 30, 2008

(54) METHOD FOR CONTROLLING HIGH-FREQUENCY RADIATOR

(76) Inventors: Kazuhiro Yahata, Osaka (JP); Takashi Uno, Hyogo (JP); Hiroyuki Sakai, Kyoto (JP); Tsuyoshi Tanaka, Osaka (JP); Daisuke Ueda, Osaka (JP)

Correspondence Address: MCDERMOTT WILL & EMERY LLP, 600 13TH STREET, NW, WASHINGTON, DC, 20005-3096, US

(21) Appl. No.: 12/109,804

(22) Filed: Apr. 25, 2008

(30) Foreign Application Priority Data
Apr. 25, 2007 (JP) 2007-114950

(51) Int. Cl. H03L 7/099

(52) U.S. Cl. 331/177 R

(57) ABSTRACT

A method for controlling a high-frequency radiator includes the steps of: (a) applying a high-frequency radiation through the solid-state oscillator and the antenna; (b) sensing part of the high-frequency radiation returned from the antenna to the solid-state oscillator; (c) adjusting radiation/propagation conditions for the high-frequency radiation on the basis of the sensed results in the step (b), the high-frequency radiation propagating from the solid-state oscillator to the antenna; and (d) after the step (c), applying the high-frequency radiation through the solid-state oscillator and the antenna to a target object. In the step (c), the oscillation frequency of the solid-state oscillator, the power of the high-frequency radiation applied by the solid-state oscillator, the power supply voltage supplied to the solid-state oscillator, the impedance match between the output impedance of the solid-state oscillator and the impedance of the antenna, or any other condition is changed.

### BACKGROUND OF THE INVENTION

(1) Field of the Invention

The present invention relates to high-frequency heaters, and more particularly relates to a method for controlling a high-frequency heater when a high-frequency radiation with high power is applied to an object to be heated.

(2) Description of Related Art

Methods for heating a high-permittivity object to be heated include a commonly used method in which the power of a microwave, a kind of an electromagnetic wave, is utilized.

In order to produce such a microwave, a magnetron having an electron tube is caused to oscillate, and an oscillatory output radiation is applied to a cavity in the magnetron, thereby heating an object to be heated. For example, for a microwave oven, the above-described cavity corresponds to a space which is called an oven and into which an object to be heated is inserted. The anode voltage of the magnetron is high so that a voltage of approximately several thousand volts is applied between electrodes. Furthermore, one magnetron is usually used for a heater of the above-mentioned type.

In some cases, a single magnetron may be used for a known heater, such as a microwave oven. In this case, the output power and output frequency of the magnetron cannot be easily changed in order to uniformly increase the temperature of an object to be heated. Such a magnetron works in a reciprocal relationship between voltage and magnetic field. This makes it difficult to change the output power of the microwave oven. Furthermore, the oscillation frequency of the magnetron depends on the configuration of electrodes of the magnetron. This makes it difficult to change the oscillation frequency using the single magnetron installed in the microwave oven. To cope with the above-described problems, an attempt has been made to replace the magnetron with a solid-state oscillator in order to uniformly and efficiently heat an object to be heated.

However, unlike magnetrons, solid-state oscillators are very likely to be broken, because solid-state oscillators are made of semiconductors. The following is generally well-known: For example, in a case where the power generated by a solid-state oscillator is radiated through an antenna, a mismatch between the impedance of the antenna seen from the solid-state oscillator and that of the solid-state oscillator seen from the antenna occurs so that the output power of the solid-state oscillator is partially returned to the solid-state oscillator, leading to the broken solid-state oscillator.

FIG. 12 is a diagram schematically illustrating a known high-frequency radiator disclosed in Japanese Unexamined Patent Application Publication No. 61-27093.

As illustrated in FIG. 12, the known high-frequency radiator has a solid-state high-frequency generator 1, a heating chamber 3 for accommodating an object to be heated (not shown), and a feed antenna 4 placed on a wall surface of the heating chamber 3. The high-frequency power generated by the solid-state high-frequency generator 1 serving as a high-frequency heat source is transmitted through a coaxial transmission line 2 to the feed antenna 4 in the heating chamber 3. The feed antenna 4 radiates the high-frequency power into the heating chamber 3 while receiving the amount of the radiated high-frequency power exceeding the amount of the high-frequency power that can be enclosed by the heating chamber 3 and inversely transmitting the excessive high-frequency power to the solid-state high-frequency generator 1. Meanwhile, an output side of the solid-state high-frequency generator 1 is provided with a directional coupler for taking the power amount proportional to the reflected power amount or a reflected power detector 5 configured by combining a circulator for taking all the reflected power and a directional coupler together. The reflected power detector 5 equivalently detects the reflected power amount from the heating chamber 3. In order to prevent a solid-state component serving as the main component of the solid-state high-frequency generator 1 from being broken, a controller 7 suspends the operation of a driving power supply 6 for the solid state high-frequency generator 1 on condition that a detection signal from the reflected power detector 5 exceeds a predetermined reference level. The known high-frequency radiator is further provided with a notifier 8 for notifying a user that high-frequency heating has been stopped on the basis of abnormal reflected power.

The above-described reference level of the detection signal is previously set according to the maximum reflected power amount determined based on the power loss amount acceptable by the solid-state component. More particularly, the reference level is set based on an acceptable power loss amount of a dummy load for absorption of reflected power. The dummy load is added to the reflected power detector 5 on condition that the reflected power detector 5 is loaded with a circulator. Such a structure can prevent the solid-state component or the dummy load from being thermally broken.

### SUMMARY OF THE INVENTION

In a known method for controlling a high-frequency radiator, it has been suggested to sense the operating state of a semiconductor and control the semiconductor before a break in the semiconductor. However, since a solid-state oscillator made of a semiconductor is very likely to be broken, it is extremely likely to be broken during the sensing of the operating state of the high-frequency radiator. Even if it escapes being broken, it is desired in view of the intrinsic way of using a high-frequency radiator to, if possible, avoid reducing the output power of the high-frequency radiator as compared with the sensed state and certainly cutting off power.

To cope with the above, in view of the above-described problems, an object of the present invention is to provide a high-frequency radiator having a solid-state oscillator and an antenna and configured to stably operate a solid-state component for generating a high-frequency radiation without breaking the high-frequency radiator and improve both heating efficiency and reliability and a method for controlling the same.

In order to achieve the above-described object, a method for controlling a high-frequency radiator according to a first aspect of the present invention is directed toward a method for controlling a high-frequency radiator including a solid-state oscillator and an antenna. The method includes the steps of: (a) applying a high-frequency radiation through the solid-state oscillator and the antenna; (b) sensing part of the high-frequency radiation returned from the antenna to the solid-state oscillator; (c) adjusting radiation/propagation conditions for the high-frequency radiation on the basis of the sensed results in the step (b), the high-frequency radiation propagating from the solid-state oscillator to the antenna; and (d) after the step (c), applying the high-frequency radiation through the solid-state oscillator and the antenna to a target object.

This method can prevent the intensity and power of the part of the high-frequency radiation returned from the antenna to the solid-state oscillator from increasing. This prevention avoids overheating of the solid-state oscillator and allows the high-frequency radiator to be driven safely. Furthermore, in the step (c), the high-frequency radiation can be applied to the target object under the optimum radiation/propagation conditions. Therefore, for example, when the target object is to be heated using a high-frequency radiation, the target object can be heated efficiently.

The intensity, power or any other element of the part of the high-frequency radiation returned to the solid-state oscillator may be sensed in the step (b). In the step (c), the sensed intensity or power may be compared to a predetermined threshold value. Alternatively, a symbol value into which the sensed power or any other sensed element is converted may be compared to a threshold value.

Moreover, in the step (c), an impedance mismatch along a high-frequency propagation path may be eliminated by various methods. Alternatively, the adjustment of the output power of the solid-state oscillator, a change in the output frequency thereof, or any other method may be executed.

Furthermore, a method for controlling a high-frequency radiator according to a second aspect of the present invention is directed to a method for controlling a high-frequency radiator including a solid-state oscillator, an antenna and a temperature sensor for sensing the temperature of the solid-state oscillator. The method includes the step of applying a high-frequency radiation through the solid-state oscillator and the antenna to a target object. When, in the application of the high-frequency radiation to the target object, the temperature sensed by the temperature sensor exceeds a predetermined threshold value, the radiation/propagation conditions for the high-frequency radiation are adjusted.

In this way, the temperature of the solid-state oscillator is sensed during the operation of the high-frequency radiator, thereby preventing overheating of the solid-state oscillator and improving the operation reliability of the high-frequency radiator.

### BRIEF DESCRIPTION OF THE DRAWINGS

FIG. 1 is a diagram schematically illustrating the basic configuration of a high-frequency heater according to a first embodiment of the present invention.

FIG. 2 is a flow chart illustrating a method for controlling a high-frequency heater of the present invention.

FIG. 3 is a diagram schematically illustrating a high-frequency heater according to a first specific example of the first embodiment.

FIG. 4 is a diagram schematically illustrating a high-frequency heater according to a second specific example of the first embodiment.

FIG. 5 is a diagram schematically illustrating a high-frequency heater according to a third specific example of the first embodiment.

FIG. 6 is a time chart illustrating a method for controlling a high-frequency heater according to a fourth specific example of the first embodiment.

FIG. 7 is a time chart illustrating a method for controlling a high-frequency heater according to a fifth specific example of the first embodiment.

FIG. 8 is a time chart illustrating a method for controlling a high-frequency heater according to a sixth specific example of the first embodiment.

FIG. 9 is a time chart illustrating a method for controlling a high-frequency heater according to a seventh specific example of the first embodiment.

FIG. 10 is a diagram schematically illustrating an example of a high-frequency heater according to a second embodiment of the present invention.

FIG. 11 is a graph for explaining a method for controlling a high-frequency heater according to the second embodiment of the present invention.

FIG. 12 is a diagram schematically illustrating a known high-frequency radiator.

### DETAILED DESCRIPTION OF THE INVENTION

Embodiments of the present invention will be described hereinafter with reference to the drawings.

### Embodiment 1

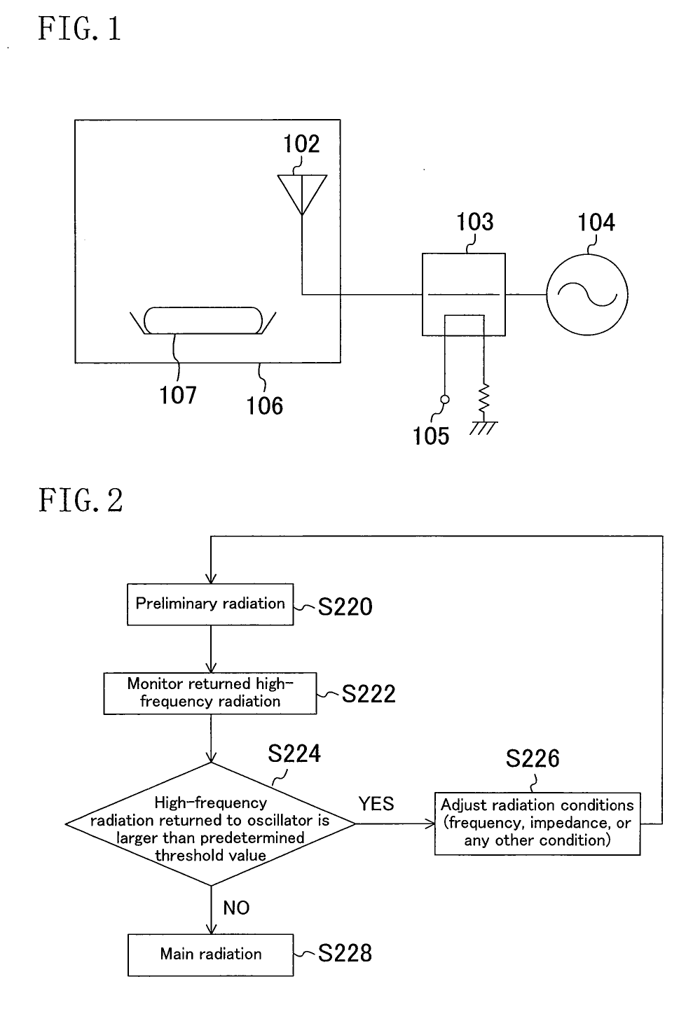

FIG. 1 is a diagram schematically illustrating the basic configuration of a high-frequency heater according to a first embodiment of the present invention. As illustrated in FIG. 1, the high-frequency heater of this embodiment includes a solid-state oscillator 104 for generating a high-frequency radiation, a directional coupler 103 for transmitting the high-frequency radiation generated by the solid-state oscillator 104, a heating chamber 106 for accommodating an object 107 to be heated (hereinafter, referred to as a “to-be-heated object 107”), and an antenna 102 placed in the heating chamber 106 to apply the high-frequency radiation transmitted through the directional coupler 103 to the heating chamber 106. The directional coupler 103 is provided with a monitor terminal 105 for monitoring high-frequency power propagating through the directional coupler 103 in the inverse direction (toward the solid-state oscillator 104). As long as the high-frequency radiation output by the solid-state oscillator 104 is a microwave, the frequency of the output high-frequency radiation is not limited. However, for example, when the high-frequency heater is a consumer-oriented microwave oven or the like, the frequency of the high-frequency radiation is 2.45 GHz.

The high-frequency radiation generated by the solid-state oscillator 104 is guided through the directional coupler 103 to the antenna 102 and then applied into the heating chamber 106 to heat the to-be-heated object 107 accommodated in the heating chamber 106. In this case, the antenna 102 applies the high-frequency radiation, receives part of the high-frequency radiation that has not been utilized to heat the to-be-heated object 107 in the heating chamber 106, and then returns the part of the high-frequency radiation to the solid-state oscillator 104. Furthermore, in a case where there is a mismatch between the impedance of the antenna 102 and the output impedance of the solid-stage oscillator 104, not only the part of the high-frequency radiation returned from the heating chamber 106 without being used but also reflected part of the high-frequency radiation are returned to the solid-state oscillator 104. The amount of the part of the high-frequency radiation returned to the solid-state oscillator 104 significantly depends on the volume, moisture content, temperature, and other elements of the to-be-heated object 107 accommodated in the heating chamber 106 and the frequency of the high-frequency radiation output at each point in time, varies with time and is not fixed. In a case where a high-frequency radiation having an extremely large amplitude is returned to the solid-stage oscillator 104, the solid-state oscillator 104 may be broken. In view of the above, the drive of the high-frequency heater of this embodiment is controlled in the later-described method.

FIG. 2 is a flow chart illustrating a method for controlling a high-frequency heater according to this embodiment.

As illustrated in FIG. 2, when a to-be-heated object is to be heated in the control method of this embodiment, the step of applying a preliminary high-frequency radiation is initially performed as step S220. In this step, the high-frequency radiation is applied only for a shorter period than that of the main radiation in which a high-frequency radiation is mainly applied.

Next, in step S222, part of the preliminary high-frequency radiation returned to the solid-state oscillator 104 (see FIG. 1) is partially taken from the monitor terminal 105, and the power of the taken part of the high-frequency radiation is monitored. Subsequently, in step S224, whether or not the power of the high-frequency radiation exceeds a predetermined threshold value is judged.

In a case where, in previous step S224, the high-frequency radiation returned to the oscillator has been judged to be larger than the threshold value, the control procedure proceeds to step S226. In step S226, the conditions on which a high-frequency radiation is applied or propagates (hereinafter, referred to as “radiation/propagation conditions”) are adjusted. More specifically, the output frequency of the solid-state oscillator 104 is changed, and an impedance mismatch is eliminated. The specific configuration and other elements of the high-frequency heater permitting the above-described operations will be specifically described below in detail. Next, after completion of step S226, the control procedure returns to step S220, and steps S222 and S224 are repeated. The intensity of the high-frequency radiation returned to the solid-state oscillator 104 varies with time. Therefore, repetitions of these steps allow the radiation/propagation conditions to be adjusted with higher accuracy. After the adjustment of the radiation/propagation conditions in step S226, the control procedure may proceed directly to step S228 in which the main radiation is performed.

Next, a high-frequency radiation is applied to the to-be-heated object under the conditions adjusted in step S226.

The use of the above-described control method allows a to-be-heated object to be heated under the previously adjusted optimum conditions for the solid-state oscillator 104. Therefore, the returned high-frequency radiation can prevent the solid-state oscillator 104 from being broken and allows the high-frequency heater to be operated with stability. In view of the above, according to the control method of this embodiment, both high heating efficiency and a high-reliability operation of the high-frequency heater can be achieved.

In the control method of this embodiment, the solid-state oscillator 104 may be configured such that the level of the high-frequency power can be amplified by an amplifier. Furthermore, the control method of this embodiment is not limited to a method in which the returned high-frequency radiation is monitored in the directional coupler 103. A high-frequency radiation flowing through a circulator may be monitored. Any monitoring measure may be taken.

In the high-frequency heater, the directional coupler 103 can be placed wherever an output signal from the solid-state oscillator 104 can be monitored. Furthermore, a member in which a high-frequency radiation is monitored does not have to be connected directly to an associated circuit and may be electromagnetically coupled to the solid-state oscillator 104 and the antenna 102.

A specific control measure in step S224 is not limited only to the measure in which the frequency is changed. Any measure does not depart from the spirit of the present invention.

The above-described control method can prevent a break in a solid-state oscillator for any device in which a high-frequency radiation is used for any purpose other than heating. However, the present invention cannot be applied to any system, such as a system for mobile telephones, in which a time chart is specified according to the standard associated with the system.

### First Specific Example of Method for Controlling High-Frequency Heater

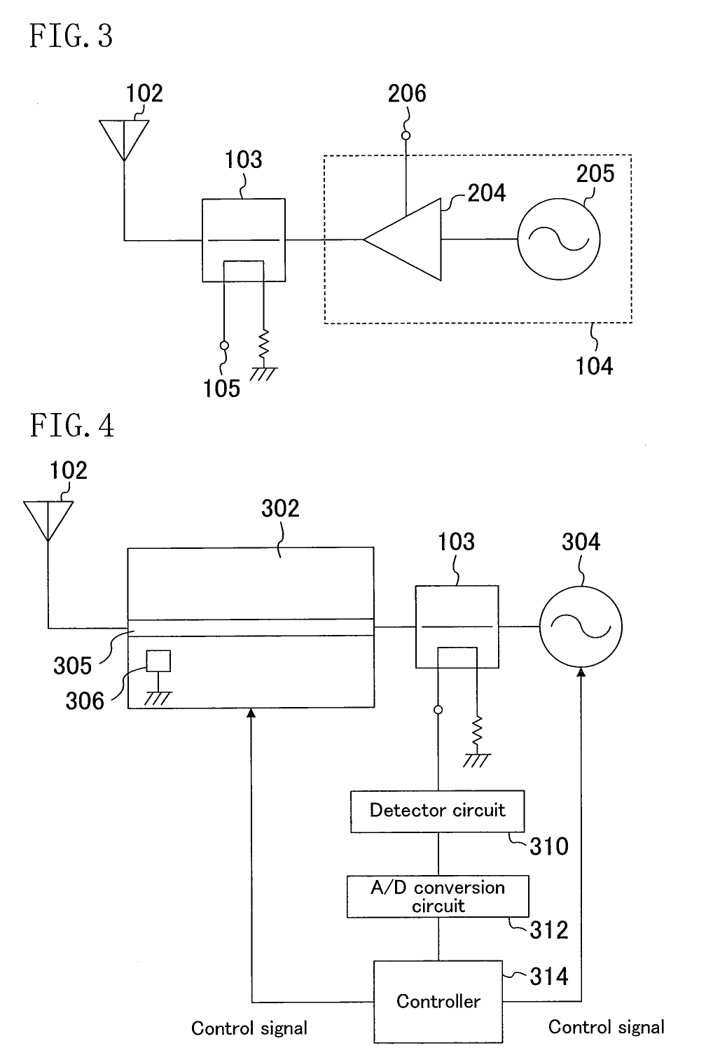

FIG. 3 is a diagram schematically illustrating a high-frequency heater according to a first specific example of the first embodiment. The high-frequency heater illustrated in FIG. 3 has basically the same configuration as that illustrated in FIG. 1. Meanwhile, in the first specific example, the solid-state oscillator 104 is composed of an oscillator 205 and an amplifier 204 connected to a bias terminal 206. In the solid-state oscillator 104, a high-frequency radiation generated by the oscillator 205 is amplified by the amplifier 204 and guided through the directional coupler 103 to the antenna 102.

The operation of the high-frequency heater according to the first specific example is controlled in accordance with the procedure of steps S220 through S228 illustrated in FIG. 2.

More particularly, the step of applying a preliminary high-frequency radiation is initially performed as step S220. Next, in step S222, part of the preliminary high-frequency radiation returned to the solid-state oscillator 104 (see FIG. 1) is partially taken from the monitor terminal 105, and the power of the taken part of the high-frequency radiation is monitored. Subsequently, in step S224, whether or not the power of the high-frequency radiation exceeds a predetermined threshold value is judged. This judgment is made by a controller (not shown) or any other device placed inside or outside the high-frequency heater.

In a case where, in previous step S224, the high-frequency radiation returned to the oscillator is larger than the predetermined value, the control procedure proceeds to step S226. In step S226, the high-frequency radiation/propagation conditions are changed. In this step, according to the method of this specific example, control over the voltage (power supply voltage) applied to the bias terminal 206 installed on the amplifier 204 changes the input/output impedance of the amplifier 204, thereby avoiding an impedance mismatch between the amplifier 204 and the antenna 201. Next, after steps S220 and S222 are again carried out and then it is recognized that the impedance mismatch has been avoided, the control procedure proceeds to step S228 in which a high-frequency radiation is mainly applied to a to-be-heated object. In a case where, in step S224, the power of the high-frequency radiation is equal to or lower than the threshold value, the control procedure proceeds to step S228 without proceeding to step S226. In step S228, the main radiation is performed under the same conditions as those of the preliminary radiation.

In above-described step S222, the threshold value that may cause a break in the solid-state oscillator 104 during the main radiation is previously determined by actual measurement, simulations or any other method, and the determined threshold value is used for the judgment on the preliminary radiation. For example, in the case of a solid-state oscillator with an output power of 100 [W], if its efficiency is 50% and its thermal resistance is 2.0 [° C./W], the amount of generated heat of the solid-state oscillator will be 100 [W], and the junction temperature thereof on condition that there is no high-frequency radiation returned to the solid-state oscillator will be approximately 200° C.

When it is assumed based on a typical absolute junction temperature rating that a junction temperature of 250° C. causes a break in a solid-state oscillator, the following is determined by calculation: When the voltage applied to an output end of the solid-state oscillator becomes 125 [W], the solid-state oscillator will be broken. More particularly, it is considered that when the high-frequency power returned from the antenna becomes 25 [W], the solid-state oscillator is broken. Consequently, it is seen from the relationship of 100 [W]=50 [dBm] and 25 [W]=44 [dBm] that the solid-state oscillator is broken at a return loss of 6 [dB] or less. The threshold value may be set at a value including a margin as compared with the threshold value determined in this embodiment.

### Second Specific Example of Method for Controlling High-Frequency Heater

FIG. 4 is a diagram schematically illustrating a high-frequency heater according to a second specific example of the first embodiment. The high-frequency heater illustrated in FIG. 4 has basically the same configuration as that illustrated in FIG. 1. However, in order to adjust the high-frequency radiation/propagation conditions, it further includes a detector circuit 310, an A/D (analog/digital) conversion circuit 312, a controller 314, and a slide-screw tuner 302.

In other words, the high-frequency heater of this specific example includes the antenna 102, the slide-screw tuner 302, the directional coupler 103, a solid-state oscillator 304, the detector circuit 310, the A/D conversion circuit 312, and the controller 314. A high-frequency radiation generated by the solid-state oscillator 304 is guided through the directional coupler 103 and the slide-screw tuner 302 to the antenna 102.

The slide-screw tuner 302 includes, for example, a 50-Ω strip line 305 and a slug 306 whose one side is grounded. The air gap between the 50-Ω strip line 305 and the slug 306 forms a capacitor. The changing of the air gap width and the location of the slug 306 allows the slide-screw tuner 302 to make an impedance match. The air gap width and the location of the slug 306 can be controlled by a control signal from the controller 314 (a microcomputer, an FPGA (field programmable gate array), or any other device).

The operation of the high-frequency heater according to the second specific example is controlled in accordance with the procedure of steps S220 through S228 illustrated in FIG. 2.

More particularly, the step of applying a preliminary high-frequency radiation is initially performed as step S220. Next, in step S222, part of the preliminary high-frequency radiation returned from the antenna 102 to the solid-state oscillator 304 during the preliminary radiation is partially taken by the directional coupler 103, and the intensity of the taken part of the high-frequency radiation is converted into voltage by the detector circuit 310. The resultant voltage is converted into a symbol value by the A/D conversion circuit 312. The controller 314 monitors this symbol value. Subsequently, in step S224, when this symbol value is compared to a threshold value previously stored in the controller 314 and consequently is larger than the threshold value, the control procedure proceeds to step S226 in which the high-frequency radiation/propagation conditions are changed.

Next, in step S226, the controller 314 changes the location of the slug 306 of the slide-screw tuner 302 and the air gap width between the 50-Ω strip line 305 and the slug 306, thereby avoiding a mismatch between the slide-screw tuner 302 and the antenna 102. Subsequently, the control procedure proceeds to step S228. In step S228, the controller 314 selects the conditions for the main radiation from the conditions for the main radiation and the conditions for the preliminary radiation and sets the conditions of the solid-state oscillator 304 and the slide-screw tuner 302 in accordance with the conditions for the main radiation. Then, the main radiation is performed.

On the other hand, when, in step S224, the symbol value is equal to or less than the threshold value, the control procedure proceeds to step S228. In step S228, the slide-screw tuner 302 is set to have the same condition as in the preliminary radiation, and then the main radiation is performed.

According to the control method of this specific example, the conditions on which a high-frequency radiation is output from the solid-state oscillator 304 and the condition of the slide-screw tuner 302 can be appropriately adjusted by the controller 314. This situation can suppress reflections from the antenna 102 with higher accuracy.

Like the solid-state oscillator illustrated in FIG. 3, the solid-state oscillator 304 may include an amplifier for receiving a bias voltage.

### Third Specific Example of Method for Controlling High-Frequency Heater

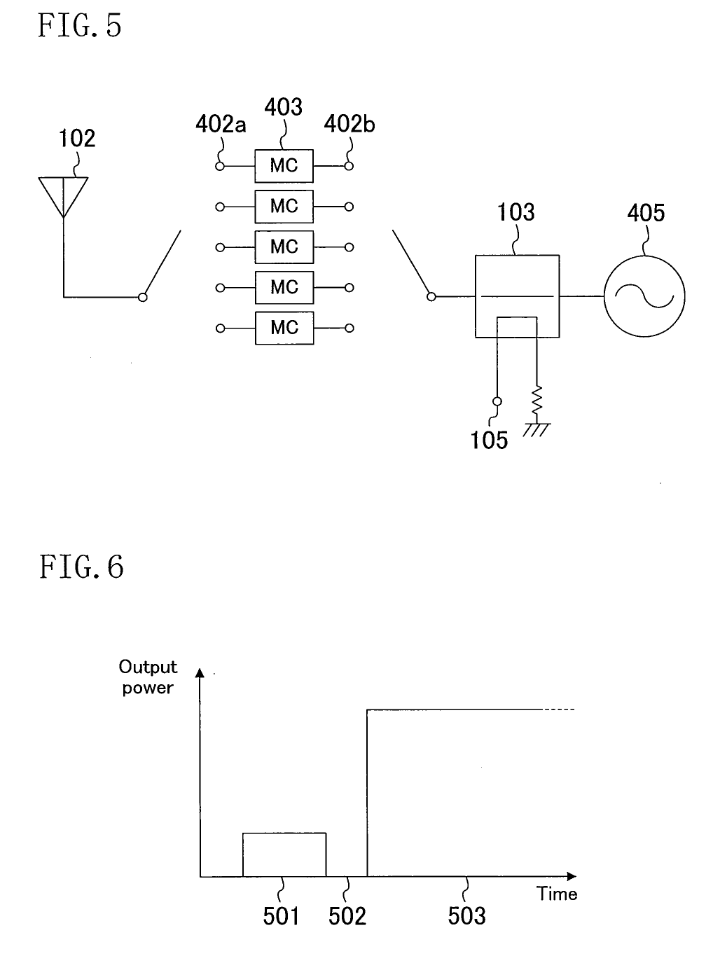

FIG. 5 is a diagram schematically illustrating a high-frequency heater according to a third specific example of the first embodiment. The high-frequency heater illustrated in FIG. 5 has basically the same configuration as that illustrated in FIG. 1. However, in this specific example, a plurality of matching circuits 403 each connected at both ends to switches 402a and 402b are placed somewhere along a high-frequency propagation path between the directional coupler 103 and the antenna 102. In this specific example, the switches 402a between the antenna 102 and the matching circuits 403 and the switches 402b between the matching circuits 403 and the directional coupler 103 operate in combination to select any one of the matching circuits 403.

In the high-frequency heater according to this specific example, a high-frequency radiation generated by a solid-state oscillator 405 is guided through the directional coupler 103, the switches 402b, at least one of the matching circuits 403, and an associated one of the switches 402a to the antenna 102. The matching circuits 403 are configured such that several types of matching conditions are achieved by an inductor, a condenser, a strip line, and any other device, and the matching circuits 403 are previously prepared.

The operation of the high-frequency heater according to the third specific example is controlled in accordance with the procedure of steps S220 through S228 illustrated in FIG. 2.

More particularly, the step of applying a preliminary high-frequency radiation is initially performed as step S220. Next, in step S222, part of the preliminary high-frequency radiation returned to the solid-state oscillator 104 (see FIG. 1) is partially taken from the monitor terminal 105, and the intensity, power or any other element of the taken part of the high-frequency radiation is detected. Subsequently, in step S224, when whether or not the intensity or power of the taken high-frequency radiation is larger than a threshold value is judged and consequently the intensity or power thereof is larger than a threshold value, the control procedure proceeds to step S226. In step S226, at least one of the matching circuits 403 is selected by the switches 402a and 402b, thereby avoiding an impedance mismatch between the antenna 102 and the solid-state oscillator 104. Thereafter, the control procedure proceeds to step S228 in which the main radiation is performed.

On the other hand, when, in step S224, the intensity or power of the high frequency is judged to be equal to or less than the threshold value, the control procedure proceeds directly to step S228. In step S228, at least one of the matching circuits 403 is appropriately selected by the switches 402a and 402b, and the main radiation is performed.

Although the high-frequency heater may include a detector circuit, an A/D conversion circuit, a controller, and any other component as illustrated in FIG. 4, the high-frequency heater may alternatively include a unit that can sense and evaluate the intensity, power or any other element of the high-frequency radiation.

### Fourth Specific Example of Method for Controlling High-Frequency Heater

FIG. 6 is a time chart illustrating a method for controlling a high-frequency heater according to a fourth specific example of the first embodiment. The axis of ordinates in FIG. 6 represents the output power of a solid-state oscillator, and the axis of abscissas therein represents time. For example, any of the high-frequency heaters according to the first through third specific examples of the first embodiment may be used for the control method of this specific example. Whatever the high-frequency radiation returned to the solid-state oscillator is, the output power of the solid-state oscillator is set at the power that does not cause a break in the solid-state oscillator even when the solid-state oscillator keeps oscillating for the longest period.

When, in view of the thermal resistance and junction temperature of a solid-state oscillator made of a semiconductor and having an output power of 100 [W], the worst conditions causing the whole power to be returned to the solid-state oscillator at a return loss of 0 [dB] are considered, the power of an output end of the solid-state oscillator is twice the output power of the solid-state oscillator. When, as in the first specific example, it is assumed that a junction temperature of 250° C. causes a break in the solid-state oscillator, a threshold value causing the break is determined as 62.5 [W] on the basis of 125 [W]/2. In the method according to this specific example, even in such a case where the power of the output end of the solid-state oscillator is twice the output power of the solid-state oscillator, the preliminary radiation is performed at a power that does not exceed the threshold value causing the break.

In view of the above, in this example, as long as the output power during the preliminary radiation is less than 62.5 [W], any high-frequency radiation returned to the solid-state oscillator does not cause a break in the solid-state oscillator. Furthermore, in consideration of variations in the output power during the preliminary radiation, an output power of 31.25 [W] obtained by further halving 62.5 [W], i.e., an output power of approximately 30 [W] or less, is considered to be an appropriate output power during the preliminary radiation.

In the method for controlling a high-frequency heater according to this specific example, the high-frequency heater is controlled basically in accordance with the procedure of steps S220 through S228 illustrated in FIG. 2.

More particularly, in FIG. 6, during the period illustrated by the reference numeral 501, the step of applying a preliminary high-frequency radiation is performed as step S220 (see FIG. 2), and the step of monitoring the high-frequency power or detecting the high-frequency radiation, for example, is performed as step S222. Next, during the period illustrated by the reference numeral 502, whether or not the high-frequency power exceeds a predetermined threshold value is judged (step S224). Furthermore, for example, in a case where the high-frequency power is judged to exceed the predetermined threshold value, the following step, for example, is performed as step S226: In this step, the high-frequency power and the frequency of the high-frequency radiation are changed, and an impedance mismatch is avoided. Next, during the period illustrated by the reference numeral 503, the main radiation is performed under the conditions selected based on the previous judgment results.

According to the control method of this specific example, the high-frequency output power during the preliminary radiation is set lower than the output power during the main radiation. This can prevent the solid-state oscillator from being broken and allows the solid-state oscillator to be operated more safely. Furthermore, use of any one of the high-frequency heaters of the first through third specific examples can improve heating efficiency and reliability.

### Fifth Specific Example of Method for Controlling High-Frequency Heater

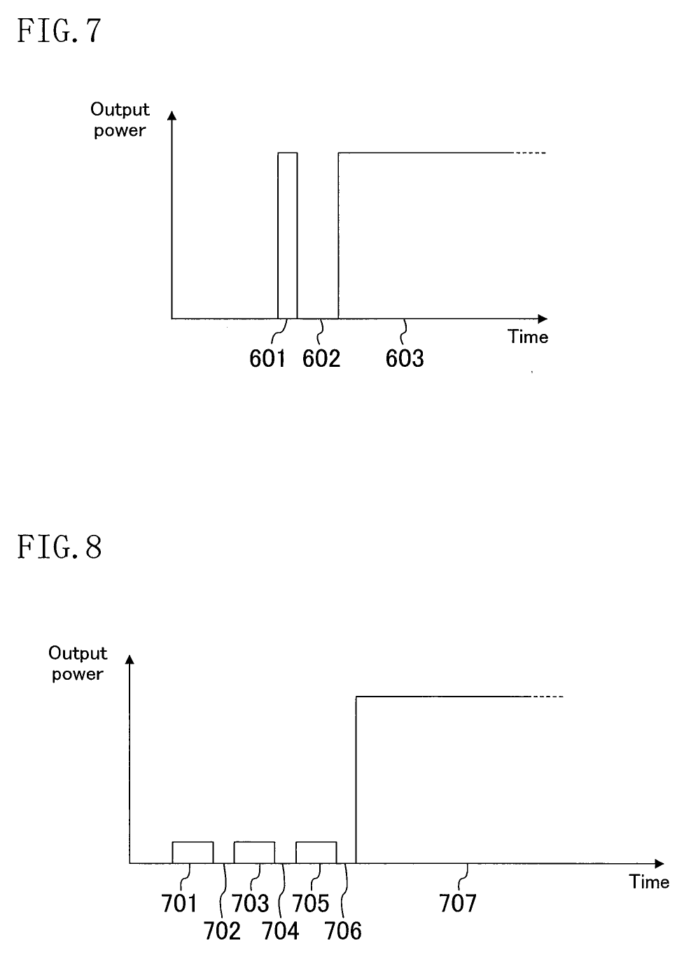

FIG. 7 is a time chart illustrating a method for controlling a high-frequency heater according to a fifth specific example of the first embodiment. The axis of ordinates in FIG. 7 represents the output power of a solid-state oscillator, and the axis of abscissas therein represents time. For example, any of the high-frequency heaters according to the first through third specific examples of the first embodiment may be used for the control method of this specific example.

In the method for controlling a high-frequency heater according to this specific example, the high-frequency heater is controlled basically in accordance with the procedure of steps S220 through S228 illustrated in FIG. 2.

More particularly, in FIG. 7, during the period illustrated by the reference numeral 601, the step of applying a preliminarily high-frequency radiation is performed as step S220, and the step of monitoring the high-frequency power or detecting the high-frequency radiation, for example, is performed as step S222. Thereafter, during the period illustrated by the reference numeral 602, the step of judging whether or not the high-frequency power exceeds a predetermined threshold value is performed as step S224. Next, for example, in a case where the high-frequency power is judged to exceed the predetermined threshold value, the following step, for example, is performed as step S226: In this step, the high-frequency power and the frequency of the high-frequency radiation are changed, and an impedance mismatch is avoided. Next, during the period illustrated by the reference numeral 603, the main radiation is performed under the conditions selected based on the previous judgment results.

In the method according to this specific example, the period spent for one preliminary radiation (hereinafter, referred to as “preliminary radiation period”) becomes shorter than the main radiation period illustrated by the reference numeral 603. In order to set the preliminary radiation period, for example, the period required to cause a break in a solid-state oscillator on condition that a high frequency radiation is reflected to a maximum extent and then totally returned to the solid-state oscillator (i.e., under a power of 200 [W]) is previously determined empirically. Accordingly, the solid-state oscillator is caused to oscillate for a period less than the determined period. More preferably, the preliminary radiation is performed for a period less than half of the determined period required to cause a break in the solid-state oscillator. In this way, the preliminary radiation can be more safely performed. With this method, even if a high-frequency radiation is applied under the conditions that long-term oscillations of a solid-state oscillator causes a break in the solid-state oscillator, a reduction in the operating period of the solid-state oscillator can prevent the solid-state oscillator from being broken due to the returned high-frequency radiation and allows the solid-state oscillator to operate more safely and stably. In view of the above, according to the method of this specific example, both heating efficiency and operation reliability of the high-frequency heater can be improved.

Furthermore, since the preliminary radiation (search) is performed at the same output power as in the main radiation, the solid-state oscillator can be more accurately operated under the optimum conditions in steps S224 and S226. The execution of the control method as described above eliminates the need for the function of changing the output level of the solid-state oscillator and provides a cost advantage.

### Sixth Specific Example of Method for Controlling High-Frequency Heater

FIG. 8 is a time chart illustrating a method for controlling a high-frequency heater according to a sixth specific example of the first embodiment. For example, any of the high-frequency heaters according to the first through third specific examples of the first embodiment may be used for the control method of this specific example. In the method for controlling a high-frequency heater according to this specific example, the high-frequency heater is controlled basically in accordance with the procedure of steps S220 through S228 illustrated in FIG. 2.

First, in FIG. 8, during the period illustrated by the reference numeral 701, the step of applying a preliminary high-frequency radiation is performed as step S220 (see FIG. 2), and the step of monitoring the high-frequency power or detecting the high-frequency radiation, for example, is performed as step S222. Next, during the period illustrated by the reference numeral 702, whether or not the high-frequency power exceeds a predetermined threshold value is judged (step S224). In a case where, in step S224, the high-frequency radiation/propagation conditions are not optimized (for example, in a case where the high-frequency power is judged to exceed the predetermined threshold value), the radiation/propagation conditions are adjusted by changing the high-frequency power and the frequency of the high-frequency radiation and avoiding an impedance mismatch (step S226). Then, during the period illustrated by the reference numeral 703, the preliminary radiation (step S220) is again performed. Subsequently, for example, the high-frequency power is again monitored, and the high-frequency radiation is detected (step S222). Next, during the period illustrated by the reference numeral 704, steps S224 and S226 are executed. Subsequently, during the periods illustrated by the reference numerals 705 and 706, steps S220 through S226 are repeated. When the radiation/propagation conditions are optimized, the main radiation is performed as step S228 during the period illustrated by the reference numeral 707.

When, as described above, the preliminary radiation and adjustment of the radiation/propagation conditions are repeated until the radiation/propagation conditions can be optimized, this repetition can increase the accuracy of the optimization and more certainly prevent the solid-state oscillator from being broken due to the returned high-frequency radiation and allows the high-frequency heater to be further stably operated. Furthermore, the solid-state oscillator can be operated under the conditions providing high heating efficiency.

In the example illustrated in FIG. 8, the operations of steps S220 through S226 are performed three times. However, the number of times that these steps are performed is not particularly limited. Furthermore, the preliminary radiation may be performed at a lower output power than that in the main radiation or at approximately the same output power.

### Seventh Specific Example of Method for Controlling High-Frequency Heater

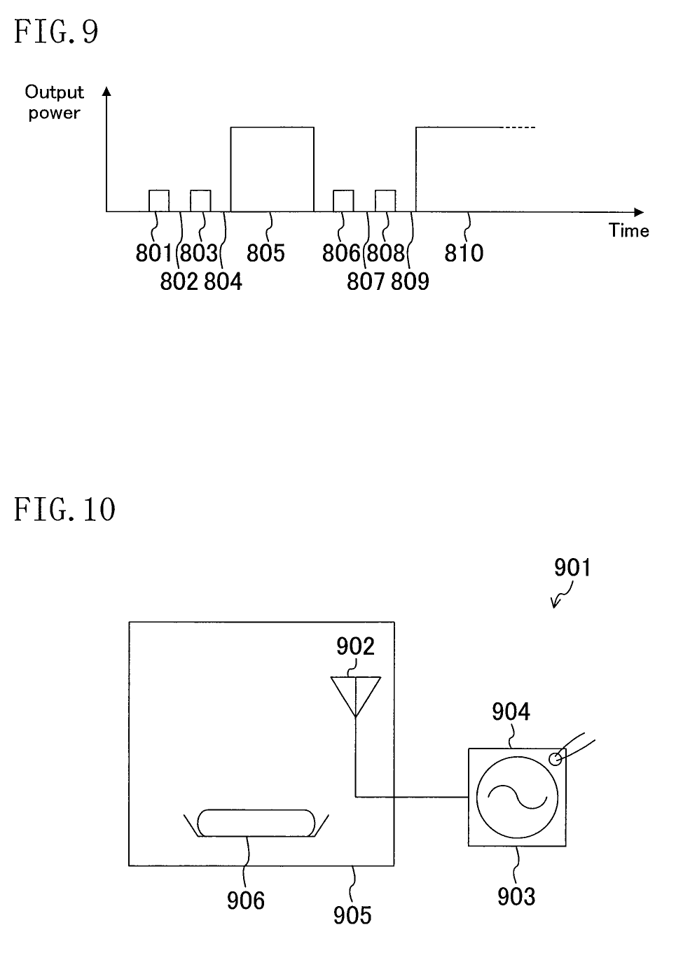

FIG. 9 is a time chart illustrating a method for controlling a high-frequency heater according to a seventh specific example of the first embodiment. For example, any of the high-frequency heaters according to the first through third specific examples of the first embodiment may be used for the control method of this specific example. Also in the method for controlling a high-frequency heater according to this specific example, the high-frequency heater is controlled basically in accordance with the procedure of steps S220 through S228 illustrated in FIG. 2.

In the method of this specific example, during the periods illustrated by the reference numerals 801, 802, 803, and 804 in FIG. 9, a combination of steps S220 and S222 illustrated in FIG. 2 and a combination of steps S224 and S226 illustrated therein are sequentially carried out a plurality of times (in this example, twice). Thereafter, during the period illustrated by the reference numeral 805, the main radiation is performed as step S228.

After the main radiation is performed for a fixed period, a combination of steps S220 and S222 and a combination of steps S224 and S226 are again sequentially carried out a plurality of times (in this example, twice) during the periods illustrated by the reference numerals 806, 807, 808, and 809. In this way, the radiation conditions are optimized, and thus, during the period illustrated by the reference numeral 810, the main radiation is performed as step S228.

As previously described, the level of the high-frequency radiation returned from an antenna varies with time and is not constant. Therefore, when, after the main radiation for a fixed period, the radiation conditions are again optimized, this optimization can more certainly prevent the solid-state oscillator from being broken and allows the high-frequency heater to be driven more safely. Furthermore, heating efficiency of the high-frequency heater can be improved, and a high-frequency radiation can be applied under high-reliability conditions.

### Embodiment 2

A second embodiment of the present invention will be described with reference to FIG. 10.

FIG. 10 is a diagram schematically illustrating an example of a high-frequency heater according to the second embodiment of the present invention.

A high-frequency heater 901 includes a solid-state oscillator 903 for generating a high-frequency radiation, a thermocouple (temperature sensor) 904 connected to the solid-state oscillator 903, a heating chamber 905 for heating a to-be-heated object 906, and an antenna 902 placed in the heating chamber 905 to receive the high-frequency radiation.

The high-frequency radiation generated by the solid-state oscillator 903 is guided to the antenna 902 and applied into the heating chamber 905 to heat the to-be-heated object 906 accommodated in the heating chamber 905. Simultaneously, the temperature of the solid-state oscillator 903 is always monitored by the thermocouple 904.

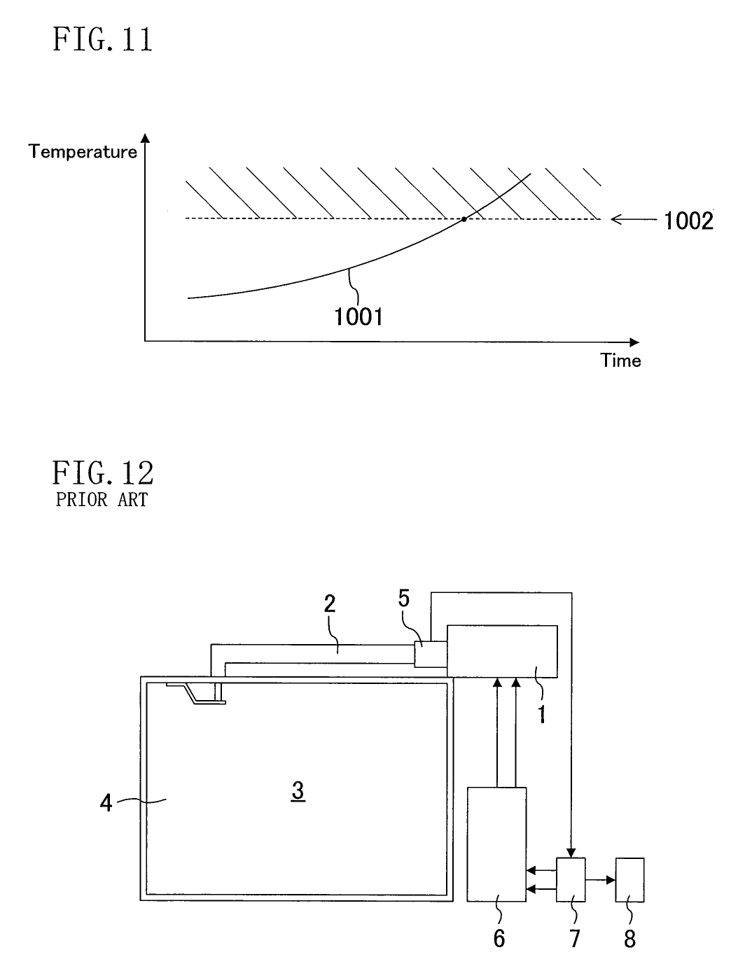

FIG. 11 is a graph for explaining a method for controlling a high-frequency heater according to the second embodiment of the present invention. The axis of abscissas in FIG. 11 represents time, and the axis of ordinates therein represents the temperature of a solid-state oscillator. In this control method, the high-frequency heater 901 illustrated in FIG. 10, for example, is used. The curve 1001 in FIG. 11 illustrates the temperature of the solid-state oscillator 903 during the operation of the high-frequency heater 901. This temperature is monitored, for example, by the thermocouple 904.

In the control method of this embodiment, the steps illustrated in FIG. 2 are basically performed. Meanwhile, in the control method of this embodiment, when, during the main radiation (step S228 in FIG. 2), the temperature of the solid-state oscillator 903 reaches a previously set threshold value 1002, the output frequency of the solid-state oscillator 903 may be changed, and alternatively the temperature of the solid-state oscillator 903 may be reduced using a unit for eliminating the above-described impedance mismatch. This threshold value 1002 may be an empirically determined temperature at which the solid-state oscillator 903 is broken (hereinafter, referred to as “breakdown temperature”). This method can more certainly prevent the solid-state oscillator 903 from being broken. In view of the above, according to the control method of this embodiment, both operation reliability and heating efficiency of the high-frequency heater can be achieved.

In the control method of this embodiment, a temperature that is in the vicinity of the breakdown temperature and lower than the breakdown temperature may be set as a risk avoidance threshold value. A certain amount of time is required to reduce the temperature of the solid-state oscillator 903 by changing the output frequency and eliminating the impedance mismatch. Therefore, when the temperature of the solid-state oscillator 903 reaches the risk avoidance threshold value, the high-frequency heater is controlled as described above, thereby reducing the temperature of the solid-state oscillator 903. This control method can certainly prevent the solid-state oscillator 903 from being broken even when it takes time to reduce the temperature of the solid-state oscillator 903.

The control method of this embodiment is combined with the control methods according to the first embodiment and the specific examples of the first embodiment, thereby more certainly preventing the solid-state oscillator 903 from being broken.

In the control method of this embodiment, in a case where it takes time to reduce the temperature of the solid-state oscillator 903, the power of the applied high-frequency radiation may be reduced. Alternatively, power may be cut off in order to suspend the application of the high-frequency radiation, and then the high-frequency heater may be again operated. However, for the purpose of efficient heating, the elimination of the impedance mismatch or a change in the output frequency more preferably prevents the solid-state oscillator 903 from being broken than the suspension of the application of the high-frequency radiation.

The thermocouple 904 illustrated in FIG. 10 is connected directly to the solid-state oscillator 903. However, this thermocouple 904 may be either connected to a substrate on which the solid-state oscillator 903 is mounted, built into the same semiconductor substrate as that for the solid-state oscillator 903, or connected to a package in which the solid-state oscillator 903 is housed.

In view of the spirit of the present invention, a measure for monitoring a temperature is not limited to a thermocouple, and any measure, such as a sensor for sensing infrared rays or a thermistor, may be used.

The high-frequency heater and the method for controlling the same as described above can be used for various devices using high frequency radiations, such as household microwave ovens or industrial or research heaters.

What is claimed is:

1. A method for controlling a high-frequency radiator including a solid-state oscillator and an antenna, the method comprising the steps of:
(a) applying a high-frequency radiation through the solid-state oscillator and the antenna;
(b) sensing part of the high-frequency radiation returned from the antenna to the solid-state oscillator;
(c) adjusting radiation/propagation conditions for the high-frequency radiation on the basis of the sensed results in the step (b), the high-frequency radiation propagating from the solid-state oscillator to the antenna; and
(d) after the step (c), applying the high-frequency radiation through the solid-state oscillator and the antenna to a target object.

2. The method of claim 1, wherein
in the step (d), the high-frequency radiation is applied to the target object, thereby heating the target object.

3. The method of claim 1, wherein
a period during which the high-frequency radiation is applied in the step (a) is shorter than a period during which the high-frequency radiation is applied in the step (d).

4. The method of claim 1, wherein
the power of the high-frequency radiation applied in the step (a) is smaller than that of the high-frequency radiation applied in the step (d).

5. The method of claim 1, wherein
in the step (b), the power of the high-frequency radiation returned to the solid-state oscillator is sensed, and
the step (c) includes the steps of (c1) comparing the power of the high-frequency radiation sensed in the step (b) to a first threshold value and (c2) adjusting the radiation/propagation conditions for the high-frequency radiation when the power of the high-frequency radiation exceeds the first threshold value.

6. The method of claim 1, wherein
in the step (b), the part of the high frequency returned to the solid-state oscillator is detected, and
the step (c) includes the steps of (c3) comparing the intensity of the part of the high-frequency radiation detected in the step (b) to a second threshold value and (c4) adjusting the radiation/propagation conditions for the high-frequency radiation when the intensity of the high-frequency radiation exceeds the second threshold value.

7. The method of claim 1, wherein
between the steps (a) and (d), the steps (b) and (c) are sequentially repeated once or more times.

8. The method of claim 1, wherein
when the high-frequency radiation is applied to the target object, the steps (a), (b), (c), and (d) are sequentially repeated once or more times.

9. The method of claim 1, wherein
the high-frequency radiator further includes a temperature sensor for sensing the temperature of the solid-state oscillator,
in the step (d), when the temperature sensed by the temperature sensor exceeds a third threshold value, the radiation/propagation conditions for the high-frequency radiation are adjusted.

10. The method of claim 1, wherein
in the step (c), at least one of the oscillation frequency of the solid-state oscillator, the power of the high-frequency radiation applied by the solid-state oscillator, the power supply voltage supplied to the solid-state oscillator, and the impedance match between the output impedance of the solid-state oscillator and the impedance of the antenna is changed.

11. A method for controlling a high-frequency radiator including a solid-state oscillator, an antenna and a temperature sensor for sensing the temperature of the solid-state oscillator, the method comprising the step of applying a high-frequency radiation through the solid-state oscillator and the antenna to a target object,
wherein when, in the application of the high-frequency radiation to the target object, the temperature sensed by the temperature sensor exceeds a predetermined threshold value, the radiation/propagation conditions for the high-frequency radiation are adjusted.

12. The method of claim 11, wherein
the threshold value is a breakdown temperature of the solid-state oscillator.
